(19) United States
(12) Patent Application Publication
(10) Pub. No.: US 2018/0168040 A1
(43) Pub. Date: Jun. 14, 2018

(54) PRINTED CIRCUIT BOARD WITH A CO-PLANAR CONNECTION

(71) Applicant: Intel Corporation, Santa Clara, CA (US)

(72) Inventors: Kannan G. Raja, Beaverton, OR (US); Nicholas W. Oakley, Portland, OR (US)

(21) Appl. No.: 15/373,921

(22) Filed: Dec. 9, 2016

(51) Int. Cl. H05K 1/14; H01R 12/72; H05K 1/02

(52) U.S. Cl. CPC H05K 1/142; H05K 2201/09163; H05K 1/0268; H01R 12/721

(57) ABSTRACT

Embodiments of the present disclosure provide techniques for a co-planar connection between a PCB and another PCB, in accordance with some embodiments. In one embodiment, a PCB may include a plurality of electric traces disposed on the PCB, and a plurality of cutouts disposed along an edge of the PCB, to interface with mating cutouts of another PCB in a co-planar connection. The electric traces may extend into respective cutouts. Adjacent cutouts of the plurality of cutouts may be placed at a distance from each other to produce a retention force in response to the interface with the mating cutouts of the other PCB, to retain the PCB in the co-planar connection with the other PCB. The electric traces may be disposed such as to form electrical connections with respective traces disposed on the mating cutouts, to provide electrical contact between the PCBs. Other embodiments may be described and/or claimed.

### FIELD

Embodiments of the present disclosure generally relate to the field of printed circuit board fabrication and testing and in particular to techniques for co-planar electrical connection for printed circuit boards.

### BACKGROUND

Current printed circuit board (PCB) testing techniques utilize methods that require connections with testing modules, often disposed on PCB as well. Typically, connections between PCB under test and testing module disposed on another PCB may require cable and/or connector or socket mechanisms. However, creating connection solutions for testing of PCB may increase overall size (e.g., z-height) of the PCB, which may negatively impact form factor requirements, particularly for PCB to be used in compact computing devices, such as smart phones or wearable devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 is a diagram illustrating an example system having a PCB coupled with another PCB in a co-planar connection, in accordance with some embodiments.

FIG. 2 illustrates some aspects of a co-planar connection between a PCB and another PCB, in accordance with some embodiments.

FIG. 3 illustrates an example configuration of a co-planar connection of a PCB with another PCB, in accordance with some embodiments.

FIG. 4 is a front view of the co-planar connection of the PCB of FIG. 3, in accordance with some embodiments.

FIG. 5 illustrates another example configuration of a co-planar connection of a PCB with another PCB, in accordance with some embodiments.

FIG. 6 illustrates still another example configuration of a co-planar connection of a PCB with another PCB, in accordance with some embodiments.

FIG. 7 is a perspective view of the co-planar connection of FIG. 6, in accordance with some embodiments.

FIG. 8 is an example process flow diagram for providing a co-planar connection between a PCB and another PCB, in accordance with some embodiments.

### DETAILED DESCRIPTION

Embodiments of the present disclosure include techniques and configurations for providing a co-planar connection between a PCB and another PCB, in accordance with some embodiments. In one embodiment, a PCB may include a plurality of electric traces disposed on the PCB, and a plurality of cutouts disposed along at least a portion of an edge of the PCB to interface with mating cutouts of another PCB in a co-planar connection. The electric traces may extend into respective cutouts of the plurality of cutouts. Adjacent cutouts of the plurality of cutouts may produce a retention force in response to the interface with the mating cutouts of the other PCB, to retain the PCB in the co-planar connection with the other PCB. The electric traces may form electrical connections with respective electric traces disposed on the mating cutouts, to provide electrical contact between the PCB and the other PCB.

In the following detailed description, reference is made to the accompanying drawings that form a part hereof, wherein like numerals designate like parts throughout, and in which are shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), (A) or (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical, electrical, or optical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

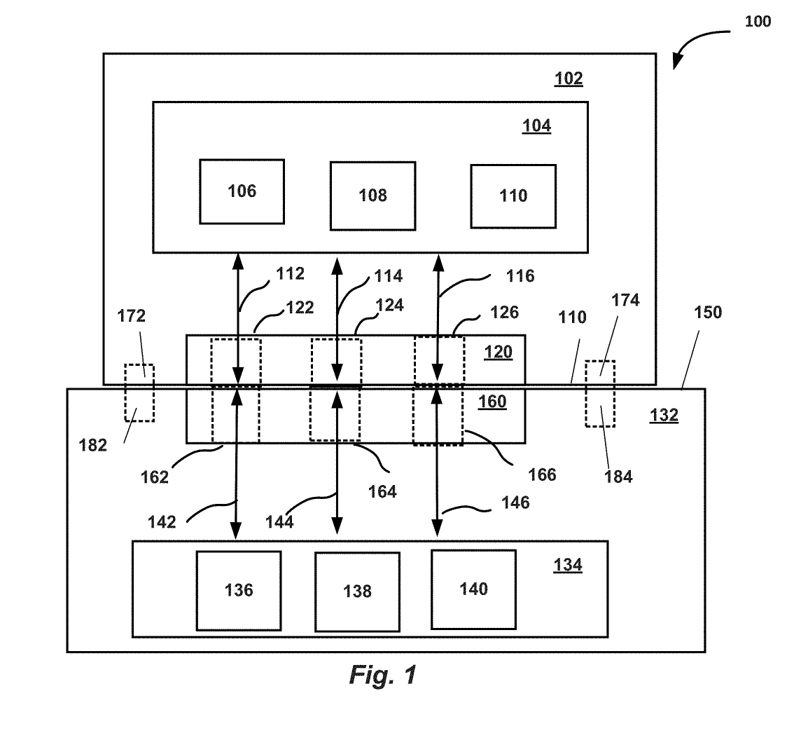

FIG. 1 is a diagram illustrating an example system having a PCB coupled with another PCB in a co-planar connection, in accordance with some embodiments. In embodiments, the system 100 may comprise a testing system. The system 100 may include a PCB 102 configured to be coupled with another PCB in a co-planar connection, in accordance with embodiments described herein. In some embodiments, the PCB 102 may comprise a testing module, and include circuitry (e.g., testing circuitry). The testing circuitry may include one or more testing modules 104, which may include multiple sub-modules 106, 108, 110. Three sub-modules are shown in FIG. 1 for ease of understanding. In general, the number of modules 104 and submodules 106, 108, 110 may vary, depending on technical characteristics and requirements to the testing equipment.

The system 100 may further include a PCB 132, couplable with the PCB 102 in a co-planar connection as described below in greater detail. In some embodiments, the PCB 132 may comprise a device under test (DUT), and may be any type of a computing device, such as a motherboard of a computing device, for example. In general, the DUT may include any sub-module or sub-modules in storage, display, or input-output system like blocks, or any add-on module or accessory block connected to a main unit. In embodiments, the PCB 132 may include one or more modules 134 (e.g., circuitry, systems on chip, or the like), which may include sub-modules 136, 138, 140. the number of modules 134 and submodules 136, 138, 140 may vary, depending on technical characteristics and requirements to the DUT.

It should be understood that the PCB 102 is described herein as a testing module, while the PCB 132 is described as a DUT for illustration purposes only. In embodiments, any one of PCB 102 or 132 may be a testing module, while another one of PCB 102 and 132 may be a DUT. Further, in some embodiments, PCB 102 and 132 may comprise devices with different functionalities that may be electrically couplable with each other in a co-planar connection for different purposes, for example, to combine the functions of the coupled PCB, to maintain a form factor with particular z-height, or the like.

The PCB 102 may be configured to connect with the PCB 132 via a connection interface 120 disposed on the PCB 102. In embodiments, the connection interface 120 may be disposed along a portion, or along the whole length of, one of the edges of the PCB 132, e.g., edge 110. For example, the connection interface 120 may include a plurality of electrical contacts (traces) 112, 114, 116 that may provide connections between the testing module 104 of the PCB 102 and another PCB (e.g., PCB 132). The traces 112, 114, 116 may extend to the edge 110 of the PCB 102, forming the connection interface 120. In some embodiments, the connection interface 120 may comprise a plurality of fingers (cutouts) 122, 124, 126, wherein the traces 112, 114, 116 may extend into respective cutouts 122, 124, 126.

The module 134 of the PCB 132 may be electrically connectable with the PCB 102 via electrical contacts (traces) 142, 144, 146, which may extend to an edge 150 of the PCB 132, forming an interface 160, to mate the interface 120 of the PCB 102. The interface 160 may be further formed by a plurality of fingers (cutouts) 162, 164, 166. The traces 142, 144, 146 may extend into respective cutouts 162, 164, 166.

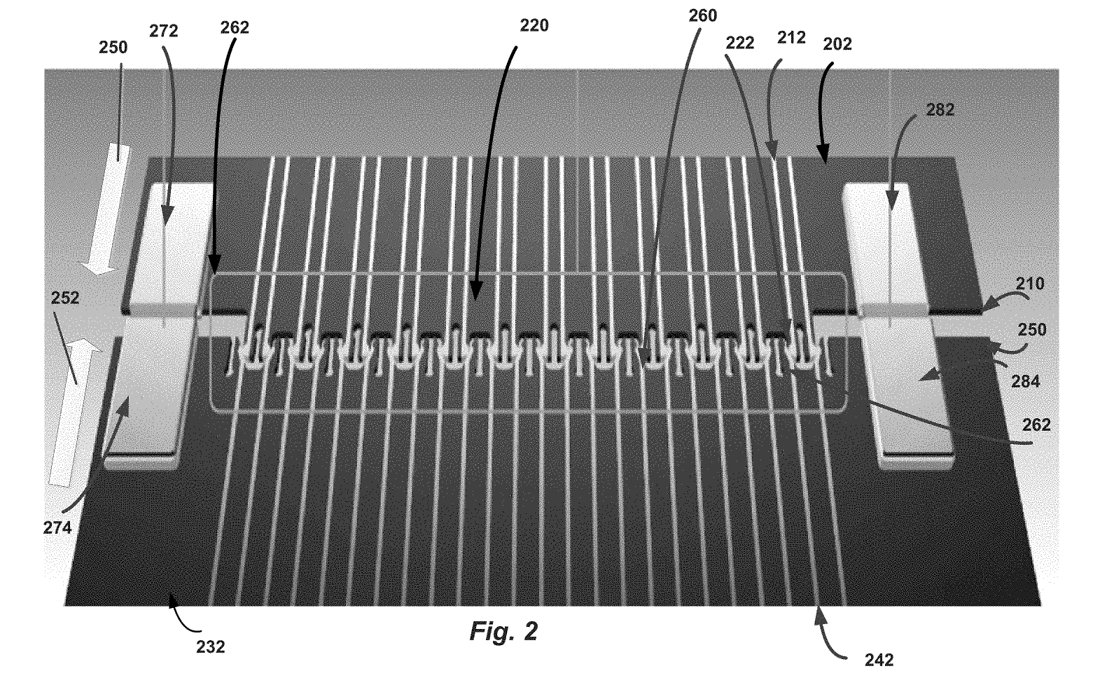

The cutouts 122, 124, and 126, and their mating cutouts 162, 164, 166 may be configured to provide a co-planar connection between the PCB 102 and 132, in response to provision of an edge-to-edge contact between the PCB 102 and 132. The edge-to-edge contact may include, for example, sliding or insertion of the interface 120 into 160, or vice versa. In response to the co-planar connection, the traces 112, 114, 116 may come into contact with respective traces 142, 144, 146, and provide electrical connection between the PCB 102 and 132. In other words, the interfaces 120 and 160 may be configured to interact with each other to form a common interface (physical and electrical) for the PCB 102 and 132. Various configurations of the cutouts of the connection interfaces 120 and 160 will be described in reference to FIGS. 2-7.

To further ensure the co-planar connection between the PCB 102 and 132, one or more latches 172, 174 may be disposed along the edge 110 of the PCB 102. Similarly, mating latches 182, 184 may be disposed along the edge 150 of the PCB 132. In response to the edge-to-edge contact, the latches 172 and 174 may meet with respective latches 182, 184, providing further retention force for the co-planar connection between the PCB 102 and 132. In embodiments, the latches 172, 174 and the mating latches 182, 184 may comprise mechanical (e.g., spring-based) or magnetic solutions. In the embodiments comprising magnetic solutions, the latch 172 may include a magnet with a polarity chosen to attract a mating magnetic of the mating latch 178, e.g., the magnets of the latches 172 and 182 may have reverse polarities. Similarly, the magnets of the latches 174 and 184 may have reverse polarities.

FIG. 2 illustrates some aspects of a co-planar connection between a PCB and another PCB, in accordance with some embodiments. PCB 202 and 232 (only portions of which are shown in FIG. 2) may be connected in a co-planar manner via their respective connection interfaces 220 and 260, similar to the embodiments of the system 100 described in reference to FIG. 1. As shown, in response to a provision of an edge-to-edge contact of the interfaces 220 and 260, a connection 262 between the PCB 202 and 232 may be formed, using particular configuration of the cutouts comprising the interfaces 220 and 260. The edge-to-edge contact may be provided by bringing together the PCB 202 and 232, as indicated by arrows 250 and 252.

As shown, the interfaces 220 and 260 may include respective cutouts (fingers) 222 and 262. Multiple traces, such as trace 212 and a mating trace 242, may be disposed to extend into respective cutouts 222 and 262, to provide electrical connection between the PCB 202 and 232. The cutouts of the interfaces 220 and 260, such as cutouts 222 and 262 may be configured to retain the PCB 202 and 232 in a co-planar, connected position.

Latches 272 and 274 and mating latches 282, 284 (similar to ones described in reference to FIG. 1) may be disposed along respective edges 210 and 250 of the PCB 202 and 232, to further retain the PCB 202 and 232 in the co-planar connection. In the example embodiment of FIG. 2, the latches may be disposed in proximity to respective ends of the edges 210, 250 of the PCB 202, 232. In some embodiments, the latches may be disposed anywhere along the respective edges 210, 250, to mate each other.

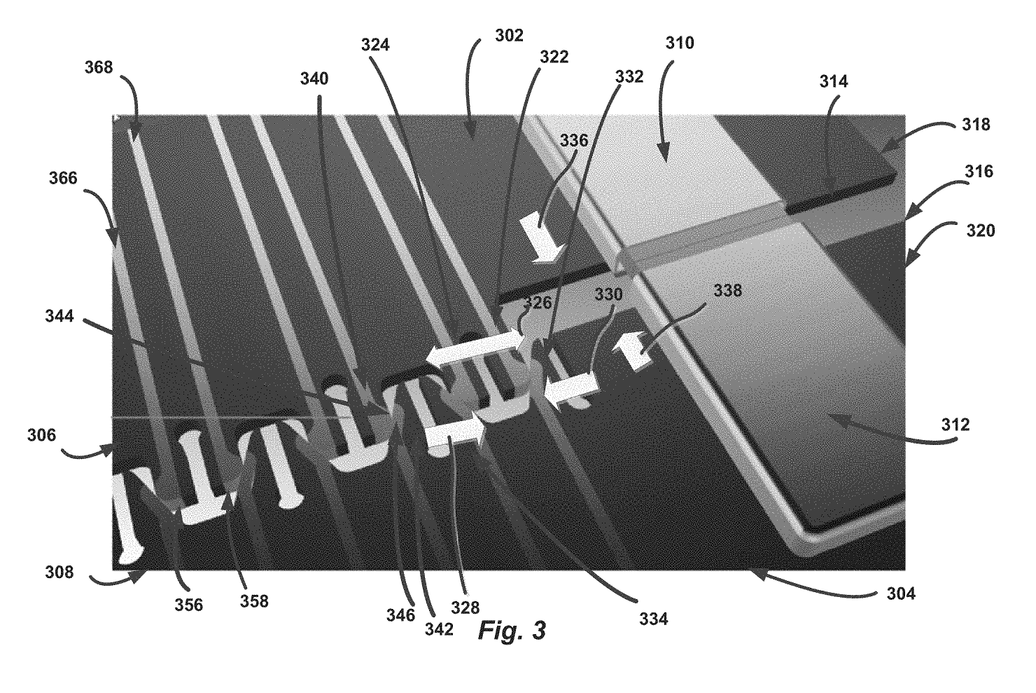

Various example configurations of the connection interfaces 220 and 260 are described in reference to FIGS. 3-6.

FIG. 3 illustrates an example configuration of a co-planar connection of a PCB with another PCB, in accordance with some embodiments. Specifically, FIG. 3 illustrates a portion of a PCB 302 co-planarly connected with a PCB 304 via respective connection interfaces 306 and 308. As shown, the PCB 302 and 304 may be further connected via respective latches 310 and 312 disposed at respective edges 314, 316 of the PCB 302, 304. As shown, in some embodiments, the latches 310 and 312 may be disposed around respective ends 318 and 320 of the PCB 302 and 304.

The interfaces 306, 308 may include a plurality of cutouts. Adjacent cutouts of one PCB (e.g., 302) may produce a retention force in response to the interface with the mating cutouts of the other PCB (e.g., 304), to retain these PCB in the co-planar connection. For example, adjacent cutouts 322, 324 of the interface 302 may produce a spring-like expansion force 326, to counteract a contraction force 328, 330, which may be produced by mating cutouts 332, 334 of the interface 308. In other words, the expansion force 326 and a corresponding contraction force 332, 334 may be produced in response to an insertion (e.g., sliding) of the interface 306 into the interface 308, indicated by arrows 336, 338. Accordingly, the adjacent cutouts 322, 324, and 332, 334 of respective interfaces 306, 308 may produce a retention force (comprising contraction force and corresponding retention force described above) in response to a contact of adjacent cutouts of the interface 306 with respective adjacent cutouts of the interface 308.

The retention forces produced by the contacts of adjacent cutouts of respective PCB may keep the PCB 302 and 304 in a co-planar connection. In order to produce a retention force, a desired amount of compliance may be built into distances between the adjacent cutouts on either connection interface 306 and 308. Further, the adjacent cutouts in either connection interface may be disposed at a distance between each other to ensure a contact of cutouts of one interface with respective cutouts of the other interface e.g., in response to insertion or sliding of one interface into another interface. In summary, interfaces 306 and 308 may form an interface for the PCB 302 and 304 that may provide for a co-planar connection of the PCB 302 and 304, which may include an electrical connections between PCB 302 and 304.

Similarly, adjacent cutouts 324, 340 of the interface 306 may produce a retention force in response to a contact with respective adjacent cutouts 334, 342 of the interface 308. As shown, the cutouts 322, 324, 340 may have a substantially polyhedral shape, wherein an edge of a cutout may form a side of the polyhedron to contact a respective side of a mating cutout. For example, the cutout 340 may have a substantially pentagon shape with a side 344 mating a side 346 of the mating cutout 342. As shown, the cutout 342 may have a substantially triangular shape.

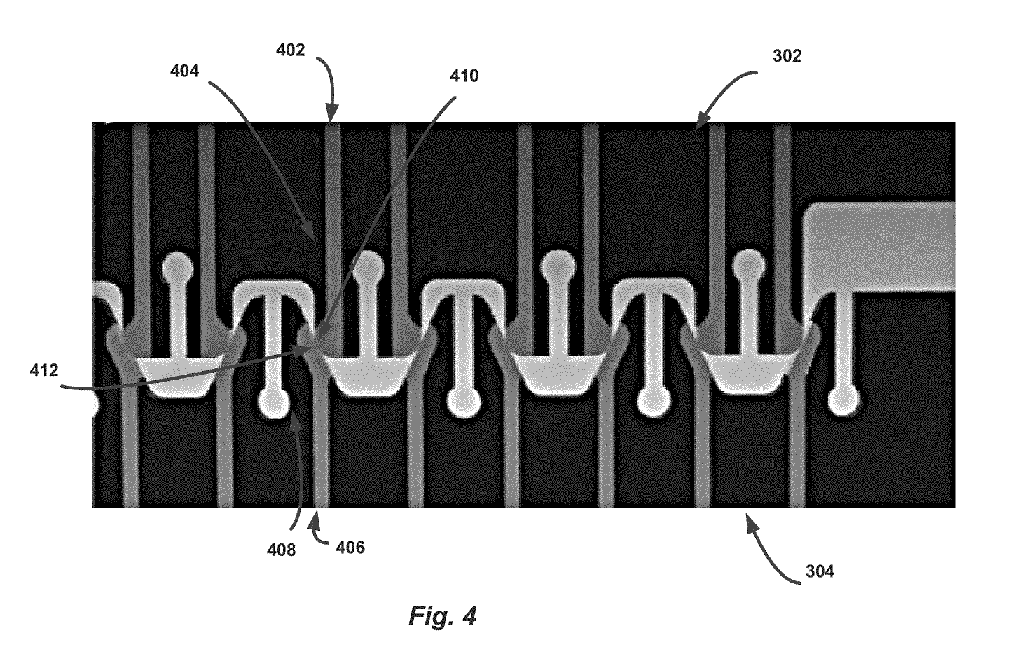

FIG. 4 is a front view of the co-planar connection of the PCB of FIG. 3, in accordance with some embodiments. As shown, electric traces (e.g., 402) may extend into cutouts (e.g., 404) to form electrical connections with respective electric traces (e.g., 406) disposed on the mating cutouts (e.g., 408), and provide electrical contact between the PCB 302 and 304. In embodiments, respective ends of the traces of one PCB (302) may form contact surfaces disposed along at least portions of the edges of the respective cutouts to form electrical contacts with respective ends of electric traces of the other PCB (304). For example, such contact surfaces may be disposed along the sides 410 and 412 of the cutouts 404 and 408. In another example, in reference to FIG. 3, contact surfaces 356 and 358 of electric traces 366 and 368 may extend along the edges of their respective cutouts, as shown. In embodiments, the edges may be at least partially curved, and the contact surfaces of the electric traces may extend along the curves.

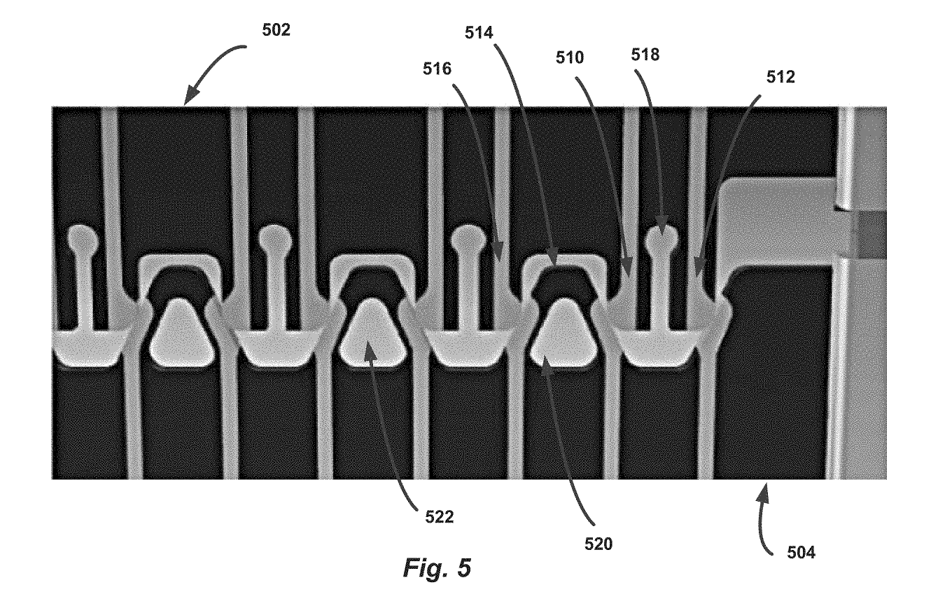

FIG. 5 illustrates another configuration of a co-planar connection of a PCB with another PCB, in accordance with some embodiments. As shown, the cutouts (e.g., 510, 512) forming a connector interface in a PCB 502 may have a substantially pentagon shape similar to those of FIGS. 3 and 4. The cutouts (e.g., 514) forming a connector interface in a PCB 504 may have a substantially triangular shape, with an aperture 520 formed between the sides of the triangle. The aperture 520 may contribute to formation of a retention force that may be produced in response to a contact between adjacent cutouts 510, 516 of the PCB 502 and mating cutouts 520 and 522 of the PCB 504. Similarly, the space 518 between the adjacent cutouts 510, 512 may serve to produce a desired retention force as described in reference to FIG. 3.

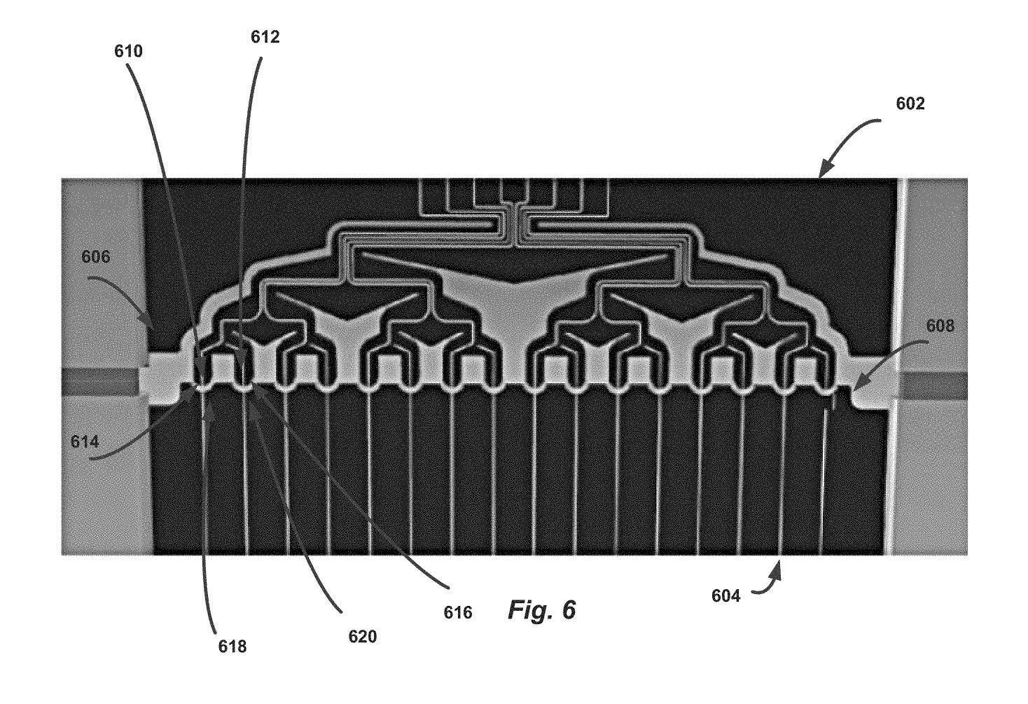

FIG. 6 illustrates still another example configuration of a co-planar connection of a PCB with another PCB, in accordance with some embodiments. PCB 602 may include a connector interface 606, and PCB 604 may include a connector interface 608. As shown, the connector interface 606 may include adjacent cutouts 610, 612, which in combination may comprise a U-shape. The ends 614 and 616 of the cutouts 610, 612 may be curved, for example at least partially rounded in a substantially convex fashion. The ends 614 and 616 may be received by mating cutouts 618, 620 of the interface 608, in response to insertion or sliding of the connector interface 606 into connector interface 608.

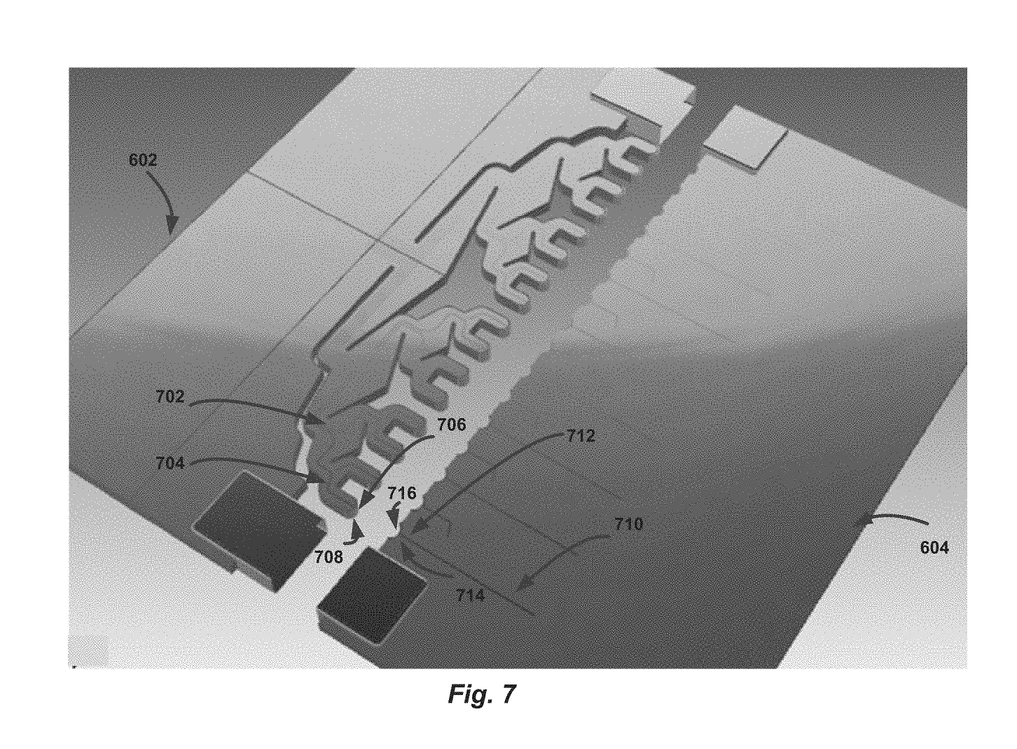

As shown, the mating cutouts 618, 620 may also be curved, e.g., may be at least partially rounded in a substantially concave fashion (e.g., in a U-shape), to mate the ends 614 and 616 of the cutouts 610, 612. The “U” shaped mating cutouts 618, 620, along with corresponding matching curved cutouts 610, 612 may help retain the boards together in a co-planar connection, and provide for electrical contacts as described in reference to FIG. 7.

FIG. 7 is a perspective view of the co-planar connection of FIG. 6, in accordance with some embodiments. As shown, the electrical traces (e.g., 702) disposed on the PCB 602 may extend into respective cutouts (e.g., 704) to reach their curved ends (e.g., 706), to form contact surfaces 708 along and around the curves, as shown. Similarly, the electrical traces (e.g., 710) disposed on the PCB 604 may extend into respective cutouts (e.g., 712) to reach their curved convex ends 714, to form contact surfaces 716 along and around the curves, to mate and retain contact with the corresponding surfaces (e.g., 708) of the mating contacts of the PCB 602.

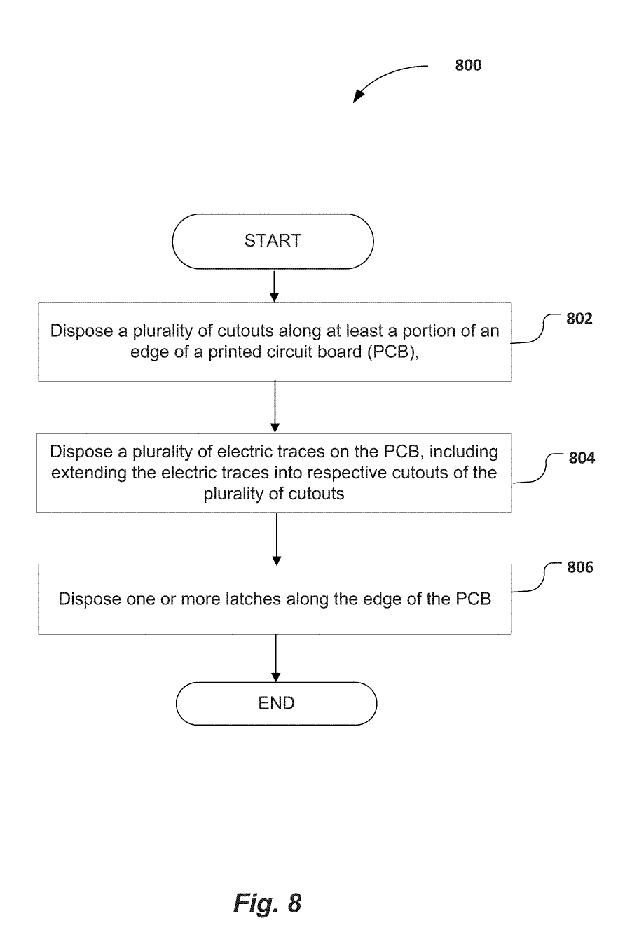

FIG. 8 is an example process flow diagram for providing a co-planar connection between a PCB and another PCB, in accordance with some embodiments.

The process 800 may begin at block 802 and include disposing a plurality of cutouts along at least a portion of an edge of a PCB. This may include providing a determined distance between adjacent cutouts to interface with mating cutouts of another PCB in a co-planar connection. The number, configuration, and types of cutouts, contacts, and modules on the PCB may depend on particular PCB design requirements. For example, if a PCB comprises a test module, a number and types of debug and test module may depend on the functionalities of a DUT to be tested. In another example, the cutouts may include a substantially polyhedral shape, a U-shape, or a triangular shape. A number of cutouts may be provided according to a number of electric traces, wherein the number of electric traces is based at least in part on a number of modules in the testing equipment. The adjacent cutouts of the plurality of cutouts are to produce a retention force in response to the interface with the mating cutouts of the other PCB, to retain the PCB in the co-planar connection with the other PCB.

At block 804, the process 800 may include disposing a plurality of electric traces on the PCB, including extending the electric traces into respective cutouts of the plurality of cutouts. Disposing electric traces may include forming contact surfaces on respective ends of the electric traces, and disposing the contact surfaces along at least portions of the edges of the respective cutouts, to provide electrical contacts with respective electric traces of the other PCB. Disposing electric traces on the PCB may include providing the electric traces of a determined plating thickness. The electric traces may form electrical connections with respective electric traces disposed on the mating cutouts, to provide electrical contact between the PCB and the other PCB.

At block 806, the process 800 may include disposing one or more latches along the edge of the PCB, to further retain the PCB in the co-planar connection with the other PCB. The other PCB may include one or more mating latches disposed on that PCB to mate the latches of the PCB in response to the co-planar connection between the PCB and the other PCB. The latches may include magnets with polarities that attract the magnets of the mating latches.

The embodiments described herein may be further illustrated by the following examples.

Example 1 may be a printed circuit board (PCB), comprising: a plurality of electric traces disposed on the PCB; and a plurality of cutouts disposed along at least a portion of an edge of the PCB to interface with mating cutouts of another PCB in a co-planar connection, wherein the electric traces extend into respective cutouts of the plurality of cutouts, wherein adjacent cutouts of the plurality of cutouts are placed at distance from each other to produce a retention force in response to the interface with the mating cutouts of the other PCB, to retain the PCB in the co-planar connection with the other PCB, wherein the electric traces are disposed on the PCB such as to form electrical connections with respective electric traces disposed on the mating cutouts, to provide electrical contact between the PCB and the other PCB.

Example 2 may include the PCB of Example 1, wherein the plurality of electric traces further extend to edges of the respective cutouts, to provide the electrical connections with the respective electric traces of the other PCB.

Example 3 may include the PCB of Example 2, wherein respective ends of the plurality of electric traces form contact surfaces disposed along at least portions of the edges of the respective cutouts, to form electrical contacts with the respective electric traces of the other PCB.

Example 4 may include the PCB of Example 3, wherein the cutouts of the plurality of cutouts have a substantially polyhedral shape, wherein an edge of a respective cutout forms at least one side of the polyhedron.

Example 5 may include the PCB of Example 4, wherein the cutouts of the plurality of cutouts have a substantially triangular shape.

Example 6 may include the PCB of Example 3, wherein the cutouts of the plurality of cutouts are substantially U-shaped.

Example 7 may include the PCB of Example 1, further comprising: one or more latches disposed along the edge of the PCB, to further retain the PCB in the co-planar connection with the other PCB, wherein the other PCB includes one or more mating latches disposed on the other PCB to mate the one or more latches in response to the co-planar connection between the PCB and the other PCB.

Example 8 may include the PCB of Example 7, wherein the co-planar connection between the PCB and the other PCB comprises an edge-to-edge contact between the PCB and the other PCB.

Example 9 may include the PCB of Example 7, wherein the one or more latches include first magnets, wherein the one or more mating latches include second magnets with respective polarities that are reverse to polarities of the first magnets.

Example 10 may include the PCB of Example 7, wherein the one or more latches include mechanical devices to latch the mating latches.

Example 11 may include the PCB of any Examples 1 to 10, wherein one of the PCB or the other PCB comprises a device under test, and wherein another one of the PCB or the other PCB comprises a test module to test the device under test.

Example 12 may include the PCB of any Examples 1 to 10, wherein the plurality of cutouts is disposed along a length of the edge of the PCB.

Example 13 may be a system with a co-planar connection, comprising: a first printed circuit board (PCB) having a plurality of first cutouts disposed along at least a portion of an edge of the first PCB, and a plurality of first electric traces that extend into respective first cutouts of the plurality of first cutouts; and a second PCB having a plurality of second cutouts disposed along at least a portion of an edge of the second PCB, and a plurality of second electric traces that extend into respective second cutouts of the plurality of second cutouts, to form electrical connections with respective ones of the plurality of first electric traces in response to provision of an interface between the first cutouts and the second cutouts, wherein adjacent ones of the first or second cutouts are to produce a retention force in response to the provision of interface with respective ones of the second or first cutouts, to retain the first and second PCB in a co-planar connection.

Example 14 may include the system of Example 13, wherein one of the first or second PCB comprises a device under test, and wherein another one of the first or second PCB comprises a test module to test the device under test.

Example 15 may include the system of Example 13, wherein adjacent ones of the first cutouts have a substantially polyhedral shape, wherein respective adjacent ones of the second cutouts have a substantially triangular shape.

Example 16 may include the system of Example 13, wherein adjacent ones of the first or second cutouts are substantially U-shaped.

Example 17 may include the system of Example 13, wherein the plurality of first electric traces further extend to edges of the respective first cutouts, wherein the plurality of second electric traces further extend to edges of the respective second cutouts, wherein respective ends of the first and second electric traces form contact surfaces disposed along at least portions of the edges of the respective first and second cutouts, to form the electrical connections in response to the interface between the first and second cutouts.

Example 18 may include the system of any Examples 13 to 17, wherein the first PCB further includes one or more first latches disposed along the edge of the first PCB, wherein the second PCB further includes one or more second latches disposed along the edge of the second PCB, to mate with the one or more first latches in response to the interface between the first and second cutouts, to further retain the first and second PCB in a co-planar connection.

Example 19 may be a method of providing a printed circuit board (PCB) with a co-planar connection, comprising: disposing a plurality of cutouts along at least a portion of an edge of a PCB, including providing a determined distance between adjacent cutouts to interface with mating cutouts of another PCB in a co-planar connection; and disposing a plurality of electric traces on the PCB, including extending the electric traces into respective cutouts of the plurality of cutouts, wherein the adjacent cutouts of the plurality of cutouts are to produce a retention force in response to interfacing with the mating cutouts of the other PCB, to retain the PCB in the co-planar connection with the other PCB, the electric traces forming electrical connections with respective electric traces disposed on the mating cutouts, to provide electrical contact between the PCB and the other PCB.

Example 20 may include the method of Example 19, wherein disposing a plurality of electric traces on the PCB includes: forming contact surfaces on respective ends of the electric traces; and disposing the contact surfaces along at least portions of the edges of the respective cutouts, to provide electrical contacts with respective electric traces of the other PCB.

Example 21 may include the method of Example 20, wherein disposing a plurality of cutouts includes forming the cutouts in one of: a substantially polyhedral shape, substantially triangular shape, or substantially U-shape.

Example 22 may include the method of Example 21, further comprising: disposing one or more latches along the edge of the PCB, to further retain the PCB in the co-planar connection with the other PCB, wherein the other PCB includes one or more mating latches disposed on the other PCB to mate the one or more latches in response to the co-planar connection between the PCB and the other PCB.

Example 23 may include the method of Example 19, further comprising: disposing testing equipment on one of the PCB or the other PCB.

Example 24 may include the method of Example 23, wherein disposing a plurality of cutouts includes providing a number of cutouts according to a number of electric traces, wherein the number of electric traces is based at least in part on a number of modules in the testing equipment.

Example 25 may include the method of any Examples 19-24, wherein disposing a plurality of electric traces on the PCB includes providing the electric traces of a determined plating thickness.

Various operations are described as multiple discrete operations in turn, in a manner that is most helpful in understanding the claimed subject matter. However, the order of description should not be construed as to imply that these operations are necessarily order dependent. Embodiments of the present disclosure may be implemented into a system using any suitable hardware and/or software to configure as desired.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims and the equivalents thereof.

1. A system, comprising:
a first printed circuit board (PCB) having a plurality of first cutouts disposed along at least a portion of an edge of the first PCB, and a plurality of first electric traces that extend into respective first cutouts of the plurality of first cutouts; and
a second PCB having a plurality of second cutouts disposed along at least a portion of an edge of the second PCB, and a plurality of second electric traces that extend into respective second cutouts of the plurality of second cutouts, to form electrical connections with respective ones of the plurality of first electric traces in response to provision of an interface between the first cutouts and the second cutouts,
wherein adjacent ones of the first or second cutouts are to produce a retention force in response to the provision of interface with respective ones of the second or first cutouts, to retain the first and second PCB in a co-planar connection.

2. The system of claim 1, wherein one of the first or second PCB comprises a device under test, and wherein another one of the first or second PCB comprises a test module to test the device under test.

3. The system of claim 1, wherein adjacent ones of the first cutouts have a substantially polyhedral shape, wherein respective adjacent ones of the second cutouts have a substantially triangular shape.

4. The system of claim 1, wherein adjacent ones of the first or second cutouts are substantially U-shaped.

5. The system of claim 1, wherein the plurality of first electric traces further extend to edges of the respective first cutouts, wherein the plurality of second electric traces further extend to edges of the respective second cutouts, wherein respective ends of the first and second electric traces form contact surfaces disposed along at least portions of the edges of the respective first and second cutouts, to form the electrical connections in response to the interface between the first and second cutouts.

6. The system of claim 1, wherein the first PCB further includes one or more first latches disposed along the edge of the first PCB, wherein the second PCB further includes one or more second latches disposed along the edge of the second PCB, to mate with the one or more first latches in response to the interface between the first and second cutouts, to further retain the first and second PCB in a co-planar connection.

7. A printed circuit board (PCB), comprising:
a plurality of electric traces disposed on the PCB; and
a plurality of cutouts disposed along at least a portion of an edge of the PCB to interface with mating cutouts of another PCB in a co-planar connection, wherein the electric traces extend into respective cutouts of the plurality of cutouts,
wherein adjacent cutouts of the plurality of cutouts are placed at distance from each other to produce a retention force in response to the interface with the mating cutouts of the other PCB, to retain the PCB in the co-planar connection with the other PCB, wherein the electric traces are disposed on the PCB such as to form electrical connections with respective electric traces disposed on the mating cutouts, to provide electrical contact between the PCB and the other PCB.

8. The PCB of claim 7, wherein the plurality of electric traces further extend to edges of the respective cutouts, to provide the electrical connections with the respective electric traces of the other PCB.

9. The PCB of claim 8, wherein respective ends of the plurality of electric traces form contact surfaces disposed along at least portions of the edges of the respective cutouts, to form electrical contacts with the respective electric traces of the other PCB.

10. The PCB of claim 9, wherein the cutouts of the plurality of cutouts have a substantially polyhedral shape, wherein an edge of a respective cutout forms at least one side of the polyhedron.

11. The PCB of claim 10, wherein the cutouts of the plurality of cutouts have a substantially triangular shape.

12. The PCB of claim 9, wherein the cutouts of the plurality of cutouts are substantially U-shaped.

13. The PCB of claim 7, further comprising: one or more latches disposed along the edge of the PCB, to further retain the PCB in the co-planar connection with the other PCB, wherein the other PCB includes one or more mating latches disposed on the other PCB to mate the one or more latches in response to the co-planar connection between the PCB and the other PCB.

14. The PCB of claim 13, wherein the co-planar connection between the PCB and the other PCB comprises an edge-to-edge contact between the PCB and the other PCB.

15. The PCB of claim 13, wherein the one or more latches include first magnets, wherein the one or more mating latches include second magnets with respective polarities that are reverse to polarities of the first magnets.

16. The PCB of claim 13, wherein the one or more latches include mechanical devices to latch the mating latches.

17. The PCB of claim 7, wherein one of the PCB or the other PCB comprises a device under test, and wherein another one of the PCB or the other PCB comprises a test module to test the device under test.

18. The PCB of claim 7, wherein the plurality of cutouts is disposed along a length of the edge of the PCB.

19. A method, comprising:
disposing a plurality of cutouts along at least a portion of an edge of a printed circuit board (PCB), including providing a determined distance between adjacent cutouts to interface with mating cutouts of another PCB in a co-planar connection; and
disposing a plurality of electric traces on the PCB, including extending the electric traces into respective cutouts of the plurality of cutouts,
wherein the adjacent cutouts of the plurality of cutouts are to produce a retention force in response to interfacing with the mating cutouts of the other PCB, to retain the PCB in the co-planar connection with the other PCB, the electric traces forming electrical connections with respective electric traces disposed on the mating cutouts, to provide electrical contact between the PCB and the other PCB.

20. The method of claim 19, wherein disposing a plurality of electric traces on the PCB includes:
forming contact surfaces on respective ends of the electric traces; and
disposing the contact surfaces along at least portions of the edges of the respective cutouts, to provide electrical contacts with respective electric traces of the other PCB.

21. The method of claim 20, wherein disposing a plurality of cutouts includes forming the cutouts in one of: a substantially polyhedral shape, substantially triangular shape, or substantially U-shape.

22. The method of claim 21, further comprising: disposing one or more latches along the edge of the PCB, to further retain the PCB in the co-planar connection with the other PCB, wherein the other PCB includes one or more mating latches disposed on the other PCB to mate the one or more latches in response to the co-planar connection between the PCB and the other PCB.

23. The method of claim 19, further comprising: disposing testing equipment on one of the PCB or the other PCB.

24. The method of claim 23, wherein disposing a plurality of cutouts includes providing a number of cutouts according to a number of electric traces, wherein the number of electric traces is based at least in part on a number of modules in the testing equipment.

25. The method of claim 19, wherein disposing a plurality of electric traces on the PCB includes providing the electric traces of a determined plating thickness.
